(19) United States
(12) Patent Application Publication
(10) Pub. No.: US 2009/0009157 A1
(43) Pub. Date: Jan. 8, 2009

(54) SYSTEM AND METHOD FOR MEASURING ENERGY IN MAGNETIC INTERACTIONS

(75) Inventors: Sean David McCarthy, Dublin (IE); Alan Simpson, Dublin (IE); Martin Flood, Dublin (IE); Maxime Sorin, Dublin (IE)

Correspondence Address: SEYFARTH SHAW LLP, WORLD TRADE CENTER EAST, TWO SEAPORT LANE, SUITE 300, BOSTON, MA, 02210-2028, US

(73) Assignee: Steorn Limited, Dublin (IE)

(21) Appl. No.: 12/166,699

(22) Filed: Jul. 2, 2008

Related U.S. Application Data
(60) Provisional application No. 60/947,474, filed on Jul. 2, 2007.

(51) Int. Cl. G01R 33/12; G01R 19/00; G01L 3/00

(52) U.S. Cl. 324/205; 324/151 R; 73/862.08

(57) ABSTRACT

An apparatus and method is provided for measuring magnetic force response time due to the magnetic viscosity of materials and for measuring total energy exchanged due to relative motion of magnetic materials. Voltage and current versus time through an electromagnet is measured and recorded. Corresponding force versus time is measured for magnetic forces applied to a material under test in response to energizing the electromagnet to determine effects of magnetic viscosity of the material under test. A test system is also provided for measuring energy exchanged due to the relative motion of magnetic materials. Absolute values of transferred mechanical energy and electrical energy are combined to determine the total energy exchanged by interaction of a permanent magnet and an electromagnet.

### CROSS-REFERENCE TO RELATED APPLICATIONS

This application claims priority to U.S. Provisional Patent Application No. 60/947,474 filed on Jul. 2, 2007.

### FIELD OF THE INVENTION

The present invention relates to test systems, and more particularly to test systems for measuring energy exchanges involving the magnetic fields of magnetic materials.

### BACKGROUND OF THE INVENTION

It may be desirable to measure the total energy exchanged due to the interaction of magnetic fields. It may also be desirable, in measuring such energy exchanges, to account for the magnetic viscosity of materials involved in the exchanges.

### SUMMARY OF THE INVENTION

The present invention provides an apparatus and method for measuring magnetic force response time due to the magnetic viscosity of materials and for measuring total energy exchanged due to relative motion of magnetic materials.

According to an embodiment of the invention, a test system for measuring magnetic force response time comprises an electromagnet mounted to a test stand and a material under test (MUT) mounted to a force gauge such that a magnetic flux linkage can be created between the electromagnet and the MUT. An oscilloscope or other test instrument is used to measure and record the voltage and current through a coil of the electromagnet and a force reading from the force gauge or other test instrument with respect to time. A step increase in magnetic flux through the MUT is created by energizing the electromagnet. The magnetic force exerted on the MUT as a result of the magnetic flux is observed on the force gauge and observed as a function of time on the oscilloscope.

The system is calibrated by accounting for the characteristic response time of the force gauge and confirming that the net effect of eddy currents in the MUT is negligible. When the electromagnet is energized, the time elapsed before a maximum magnetic force is reached is measured on the MUT. The direction of the current applied to the electromagnet is reversed to measure the effect on the MUT of a magnetic field in the opposite direction.

In the illustrative embodiment, the MUT comprises a partially de-magnetized permanent magnet. The magnetic viscosity of the MUT is therefore much greater than the viscosity of the ferromagnetic core of the electromagnet. Accordingly, this rise time of measured force on the MUT is attributed almost exclusively to the time needed to align magnetic domains in the MUT. A pulse generator can be used in combination with a relay to repeatedly energize the electromagnet. The method and apparatus of the illustrative embodiment can be used to measure the rise time and maximum force produced upon each cycle, or upon a sampling of cycles of the pulse generator to demonstrate the effect of repeated magnetic interactions on a MUT.

According to another embodiment of the invention, a test system for measuring energy exchanged due to the relative motion of magnetic materials comprises a permanent magnet mounted on a disk. The disk is revolved about its axis of rotation to establish a circular path of the permanent magnet. A passive electromagnet is mounted proximate to the circular path of the permanent magnet. Current that is induced in the electromagnet is measured and recorded for corresponding angular displacements of the permanent magnet around the circular path. Torque on the disk is also measured for corresponding angular displacements of the permanent magnet around the circular path. The magnetic flux density in the electromagnet is calculated as a function of the current for corresponding angular displacements of the permanent magnet. The mechanical energy transferred to the disk is calculated as a function of measured torque versus angular displacement of the permanent magnet for a given angular velocity of the disk. The electrical energy transferred to the electromagnet is calculated as a function of the measured current in the electromagnet for a given angular velocity of the disk. The absolute values of the transferred mechanical energy and electrical energy are combined to determine the total energy exchanged by interaction of the permanent magnet and electromagnet.

The illustrative embodiments of the invention provide a system and method for demonstrating that the absolute net energy of a ferromagnetic interaction varies as a function of the relative velocities of magnetic materials involved in the interaction. The embodiments provide a system and method for demonstrating that the variations of absolute net energy as a function of speed are due to the magnetic viscosity of the materials involved in the interaction. Accordingly, embodiments of the present invention can be used to demonstrate that the absolute energy of a magnetic transaction can be controlled by controlling the speed of the interaction.

### BRIEF DESCRIPTION OF THE DRAWINGS

The foregoing and other features and advantages of the present invention will be better understood from the following detailed description of illustrative embodiments, taken in conjunction with the accompanying drawings in which:

FIG. 1 is a diagram of a test apparatus for measuring magnetic force response time according to an embodiment of the invention;

FIG. 2 is a process flow diagram showing the steps of measuring magnetic force response time according to an embodiment of the invention;

FIG. 3 is a graph of force versus time illustrating the results of a ring test performed by applying impulses of different amplitudes on a material under test as measured according to an embodiment of the invention;

FIG. 4 is a graph of force and current versus time illustrating a lag time in force registration as measured according to an embodiment of the invention;

FIG. 5 is a graph showing a repulsive force applied to a material under test due to magnetic flux generated by energizing a coil as measured according to an embodiment of the invention;

FIG. 6 is a graph showing an attractive force applied to a material under test in response to magnetic flux generated by energizing the coil as measured according to an embodiment of the invention;

FIG. 7 is an initial force versus time graph showing the force lag time due to magnetic viscosity in a material to be used in the repetition test and measured according to an embodiment of the invention;

FIG. 8 is a force versus time graph acquired after a repetition test performed and measured according to an embodiment of the invention;

FIG. 9 is a diagram of a test apparatus for measuring energy exchanged due to relative motion of magnetic materials according to an embodiment of the invention;

FIG. 10 is a process flow diagram showing the steps of measuring energy exchanged due to relative motion of magnetic materials according to an embodiment of the invention;

FIG. 11 is a graph showing torque versus angular displacement of the disk for different relative speeds of magnetic members as measured according to an embodiment of the invention.

FIG. 12 is a graph of the magnetic flux within an electromagnet versus angular displacement of a disk for different rotational speeds of the disk as measured according to an embodiment of the invention;

FIG. 13 is a graph of torque and magnetic flux versus angular position of a disk when the rotational speed of the disk is 1 RPM as measured according to an embodiment of the invention;

FIG. 14 is a graph of torque and flux versus angular position of a disk when the rotational speed of the disk is 10,000 RPM as measured according to an embodiment of the invention;

FIG. 15. is a graph showing a magnitude of the flux versus angular position of the disk as measured according to an embodiment of the invention; and

FIG. 16 is a graph showing total absolute value of mechanical energy and induced electrical energy exchanged during a revolution of a disk as a function of the rotational speed of the disk as measured according to an embodiment of the invention.

### DETAILED DESCRIPTION

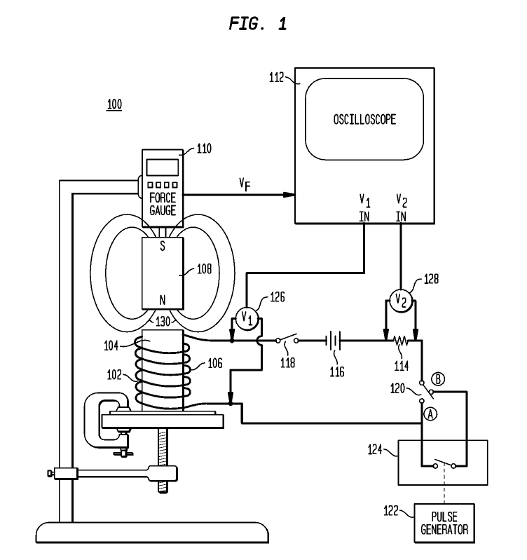

A system for measuring magnetic force response time 100 as illustrated in FIG. 1 is comprised of a number of components including an electromagnet 102 illustratively consisting of a core 104 and a coil 106 having a number of turns disposed around the core 104. The electromagnet is a fast acting air coil electromagnet that can be used to generate a step change in magnetic flux. In an illustrative embodiment, the coil 106 has an external diameter of 7 mm and consists of eight turns of 1.5 mm diameter wire insulated by polyurethane. The electromagnet 102 is held rigidly in place relative to a material under test (MUT) 108 such as a permanent magnet. In an illustrative embodiment, the MUT 108 is a partially demagnetized neodymium magnet. The MUT 108 is attached to a piezoelectric force sensor incorporated in a force gauge 110 having an output suitable for connection to an oscilloscope 112. The oscilloscope 112 measures and records the force exerted upon the MUT 108 with respect to time.

In order to generate a step change in magnetic flux, the electromagnet 102 is connected in series with a resister 114, a direct current DC power source 116 and a first switch 118. Illustratively, the resister is a 2.8 ohm resister and the DC power source 116 is a 24 volt DC battery. A second switch 120 is illustratively provided to enable a repeatable step change in magnetic flux by connecting a pulse generator 122 and relay 124 to the coil 102. A voltage (V1) 126 across the coil 102 and a voltage (V2) 128 across the resistor 114 are measured with respect to time by the oscilloscope 112.

An air gap 130 is provided between the coil 102 and the MUT 108. Illustratively, the air gap 130 is adjustable. A typical air gap of 2 mm in the illustrative embodiment results in generation of a magnetic flux of 1.6 mT.

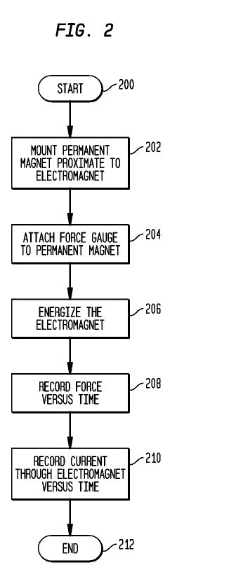

A method of measuring magnetic force is described with reference to the process flow diagram of FIG. 2 which starts at step 200. A MUT such as a permanent magnet is mounted 202 proximate to an electromagnet so that magnetic flux created in the electromagnet applies a force to the MUT. The MUT is connected 204 to a force gauge for measuring the force applied to the MUT. The electromagnet is then energized 206. Force measurements are output from the force gauge to an oscilloscope which records 208 and/or displays the measured force versus time. Current through the electromagnet is also measured and recorded 210 by an oscilloscope. To measure the current through the coil, the oscilloscope is illustratively connected to measure a voltage (e.g., 128 of FIG. 1) across a resistor in series with the coil (e.g., 114 of FIG. 1) which is divided by the value of the resister to yield the current through the coil. The process is completed at step 212.

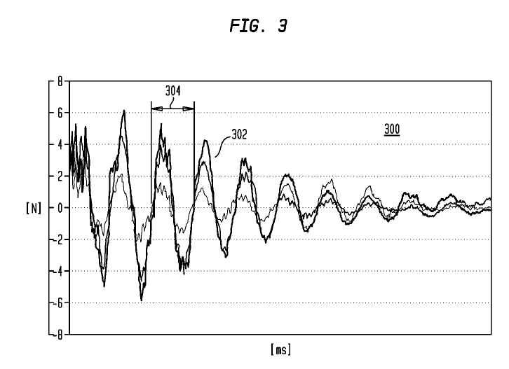

A ring test can be performed in order to measure the mechanical response time of the system shown in FIG. 1. The ring test is performed by applying a mechanical impulse to the mounted MUT and recording the force versus time output by the force gauge or other test instrument in response to the impulse. FIG. 3 is a graph 300 of force versus time illustrating the results of such a ring test performed by applying impulses of different amplitudes. It is observed that the measured force versus time curves 302 have the same period of oscillation 304, about 2.45 ms, regardless of the strength of impulse applied to the MUT.

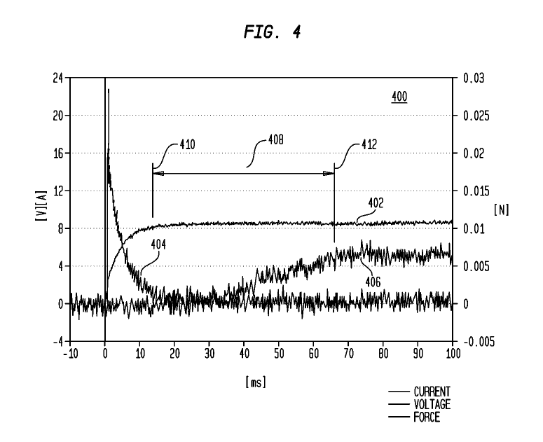

A lag time in force registration is observed with reference to the graph 400 shown in FIG. 4. Current 402 through the coil of the electromagnet, voltage 404 across the coil of the electromagnet, and force 406 measured by the force gauge in response to the current is plotted as a function of time. A time lag 408 of about 52 μs is observed between registration of full current 410 and registration of full force 412. Since the magnetic field created by energizing a coil propagates at the speed of light there is virtually no lag time associated with propagation of the field. Accordingly, the time lag 408 represents the response time of the force gauge.

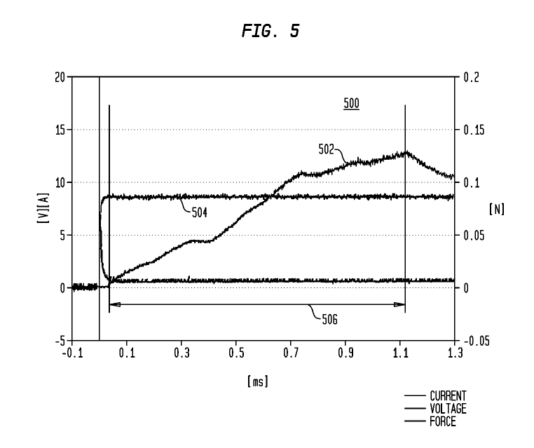

FIG. 5 is a graph showing a repulsive force applied to the MUT, a partially demagnetized neodymium magnet, in response to magnetic flux generated by energizing a coil using the system shown in FIG. 1. In this example, the second switch 120 is in position ‘A’ to remove the pulse generator 122 and the 124 from the energizing circuit. The first switch 118 is closed to energize the coil 102. The graph 500 shows the force 502 measured when a current 504 is applied to the coil. A rise time 506 of about 1.13 ms due to magnetic viscosity in the MUT is observed from the time of peak current to the time of peak force.

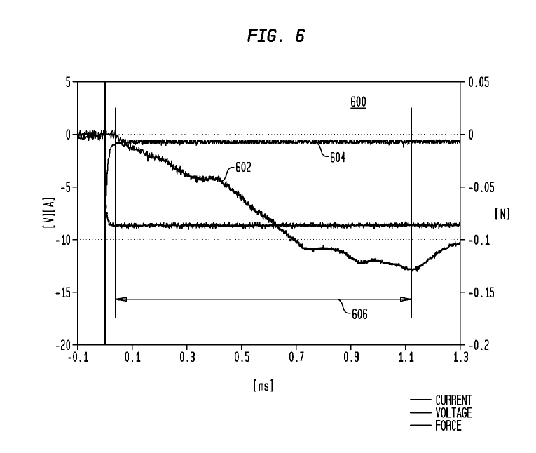

FIG. 6 is a graph showing an attractive force applied to the MUT in response to magnetic flux generated by energizing the coil using the system shown in FIG. 1. The polarity of the DC power source (116, FIG. 1) energizing the coil is reversed to reverse the direction of magnetic flux and thereby apply an opposite magnetic force to the MUT. In this example, the second switch 120 is still in position ‘A’ to remove the pulse generator 122 and the relay 124 from the energizing circuit. The first switch 118 is again closed to energize the coil 102. The graph 600 shows the force 602 measured when a current 604 is applied to the coil. A rise time 606 of about 1.13 ms is observed from the time of peak current to the time of peak force. This demonstrates that force lag time due to magnetic viscosity in the MUT is the same regardless of whether the applied magnetic field is attractive or repulsive.

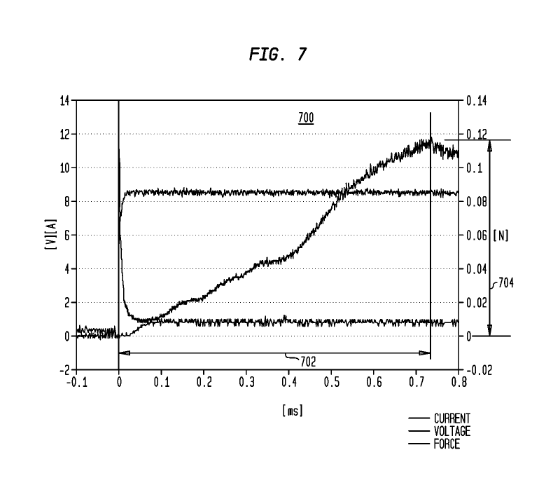

A repetition test is performed using the system shown in FIG. 1. FIG. 7 is an initial force versus time graph 700 showing the force lag time 702 of about 0.737 μs due to magnetic viscosity in the MUT that will be used in the repetition test. The force 704 generated by the magnetic interaction is about 0.115 N. Once the initial lag time is measured, the system is configured for the repetition test by placing the second switch 120 in position ‘B’ to include the pulse generator 122 and relay 124 in the coil energizing circuit and closing the first switch 118. The pulse generator 122 provides a stream of pulses to repeatedly open and close the relay 124 which, in turn, repeatedly energizes and de-energizes the coil 102.

FIG. 8 is a force versus time graph 800 acquired after 840,000 cycles of energizing and de-energizing the coil. The graph 800 shows a force lag time 802 of about 721 μs and a force 804 of about 0.115 N generated by magnetic interaction. A difference in lag time of about 16 μs, or about 2%, is observed between the initial measurements (FIG. 7) and final measurements (FIG. 8) after the repetition test. No difference in the force of magnetic interaction is observed.

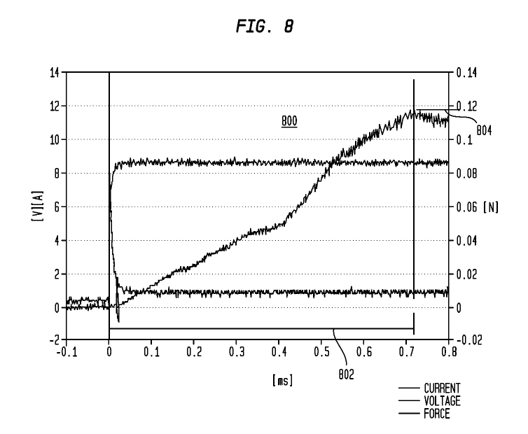

A system for measuring energy exchange due to the relative motion of magnetic materials is described with reference to the illustrative embodiment shown in FIG. 9. In the illustrative embodiment, a permanent magnet 902 is mounted to disk 904 having an axis of rotation 906. The disk 904 is revolved about its axis of rotation 906 to establish a circular path of the permanent magnet 902. A passive electromagnet 908 is mounted proximate to the circular path of the permanent magnet 902. The passive electromagnet consists of a number of turns 910 of wire wrapped around a ferromagnetic core 912. A resistor 914 is connected across the coil 901 and one terminal of the resistor 914 is connected to ground 916.

Changing magnetic fields in the electromagnet 908 caused by motion of the permanent magnet 902 about the circular path induce current in the coil 908. The induced current versus time is measured and recorded by an oscilloscope for corresponding angular displacements 918 of the permanent magnet 902 around the circular path. Torque on the disk 904 is also measured for corresponding angular displacements of the permanent magnet around the circular path.

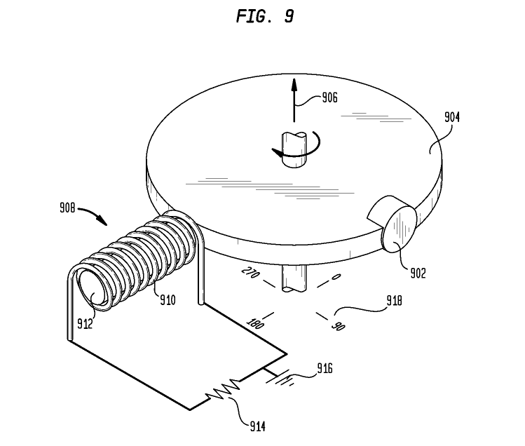

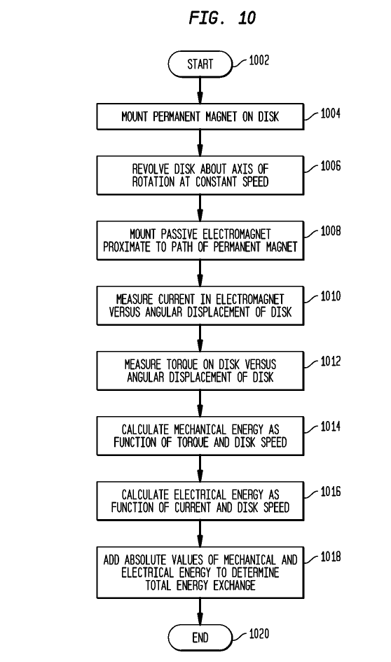

A method of measuring energy exchange due to the relative motion of magnetic materials is described with reference to the process flow diagram of FIG. 10 which starts at step 1002. According to the illustrative method, a permanent magnet is mounted 1004 on a disk. The disk is revolved 1006 about its axis of rotation at a constant speed. A passive electromagnet is mounted 1008 proximate to the path of rotation of the permanent magnet. Current induced in the electromagnet versus angular displacement of the disk is measured 1010. Torque on the disk versus angular displacement of the disk is measured 1012 simultaneously with the current measurement. In the illustrative embodiment, the current measurement is recorded by an oscilloscope and the torque measurement is measured by a torque transducer connected to the oscilloscope.

The magnetic flux density in the electromagnet is calculated as a function of the current for corresponding angular displacements of the permanent magnet. The mechanical energy transferred to the disk is calculated 1014 as a function of measured torque versus angular displacement of the permanent magnet for a given angular velocity of the disk. The electrical energy transferred to the electromagnet is calculated 1016 as a function of the measured current in the electromagnet for a given angular velocity of the disk. The absolute values of the transferred mechanical energy and electrical energy are combined 1018 to determine the total energy exchanged by interaction of the permanent magnet and electromagnet. The process is completed at step 1020.

As the disk is rotated at different fixed speeds, the torque on the disk and the flux density of the iron core are plotted as a function of the angular displacement of the disk. Illustratively, the zero degree position is defined as the position of the disk where the permanent magnet is furthest away from the electromagnet, but directly in line with it. The 180 degree position is where the permanent magnet is closest to the electromagnet. In FIG. 9, the disk is shown in the 90 degree position.

The disk is rotated at speeds of 1, 10, 100, 1000, and 10,000 revolutions per minute (RPMs). For each rotational speed, the torque on the disk and the flux density within the electromagnet are calculated.

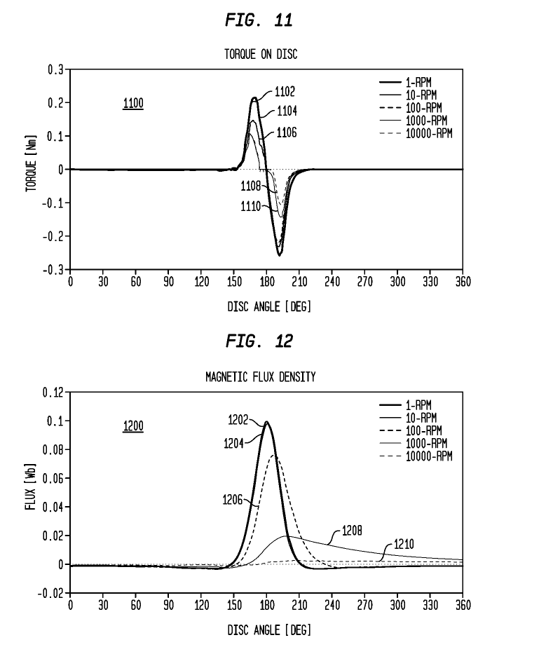

A graph of the measured torque versus angular displacement of the disk for each rotational speed is shown in FIG. 11. The graph 1100 shows the torque at rotational speeds of 1 RPM 1102, 10 RPM 1104, 100 RPM 1106, 1000 RPM 1108 and 10,000 RPM 1110. A graph of the measured magnetic flux within the electromagnet versus angular displacement of the disk for each rotational speed is shown in FIG. 12. The graph 1200 shows the magnet flux at speeds of 1 RPM 1202, 10 RPM 1204, 100 RPM 1206, 1000 RPM 1208 and 10,000 RPM. It is observed with reference to FIG. 11 and FIG. 12 that when the constant rotational speed of the disk is stepped up from 1 RPM to 10,000 RPM, the torque acting on the disk is reduced from about 0.22 Nm to about 0.10 Nm. This reduction in torque is attributable to the finite alignment time of magnetic domains in the ferromagnetic core of the electromagnet, i.e. its magnetic viscosity. In FIG. 12, it is observed that as the constant rotational speed of the disk is stepped up from 1 RPM to 10,000 RPM, the peak flux values move to the right from the 180 degree position, where the permanent magnet is closest to the electromagnet, to about the 210 degree position of the disk. Both the reduction in torque and the shift of the peak flux values are produced as a result of the magnetic viscosity of the electromagnet.

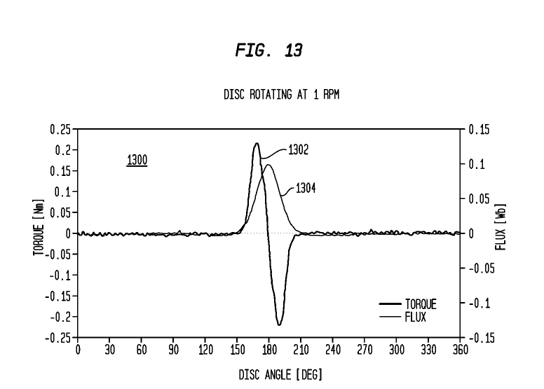

FIG. 13 is a graph 1300 of torque 1302 and magnetic flux 1304 versus angular position of the disk when the rotational speed of the disk is 1 RPM. A maximum torque of about 0.22 Nm and a maximum flux of about 0.1 Wb is observed. It is also observed that at about 1 RPM the peak flux value and cross over of the torque curve occur at the 180 degree position of the disk. This indicates that there is no noticeable shift of the peak flux value and no noticeable effect of the electromagnet's magnetic viscosity when the disk is rotated at a constant speed of 1 RPM.

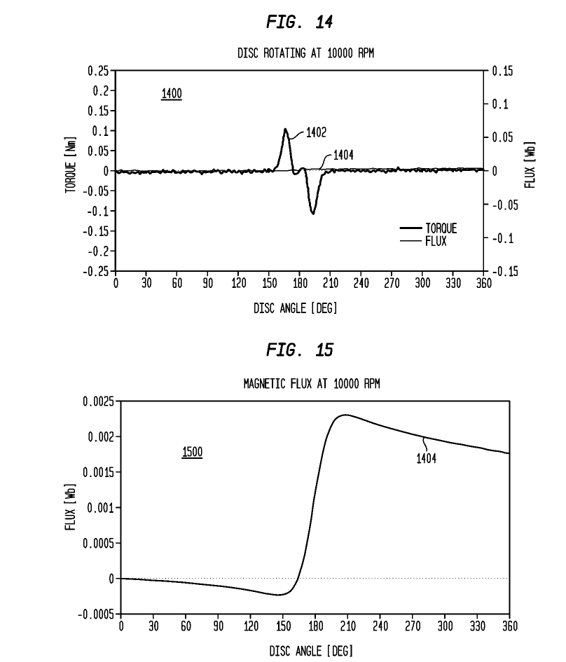

FIG. 14 is a graph 1400 of torque 1402 and flux 1404 versus angular position of the disk when the rotational speed of the disk is 10,000 RPM. A maximum torque of about 0.10 Nm and a maximum flux of about 0.0023 Wb is observed. FIG. 15. is a graph 1500 having a scale that more clearly shows the magnitude of the flux 1404 versus angular position of the disk. Again, it is observed that, due to the magnetic viscosity of magnetic materials in the system, the peak torque value of the magnetic transaction is much smaller when the disk is rotated at a constant speed of 10,000 RPM than it is when the disk is rotated at constant speed of 1 RPM. In FIG. 15 it is observed that, due to the magnetic viscosity of the magnetic materials in the system, when the disk is rotated at 10,000 RPM, the flux within the electromagnet peaks at a disk position of about 210 degrees with a much lower peak flux value than was observed at 1 RPM.

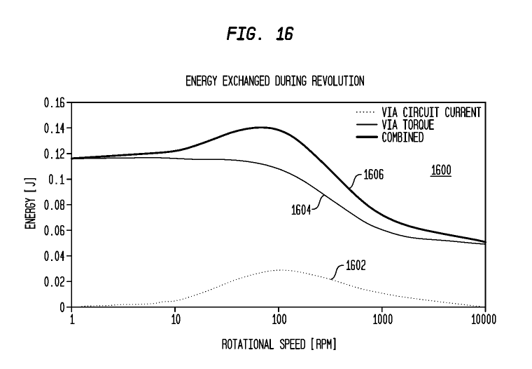

FIG. 16 is a graph 1600 showing the total absolute value of mechanical energy and induced electrical energy exchanged during a revolution of the disk as a function of the angular velocity of the disk. A plot of the energy calculated by measuring induced current in the electromagnet's coil for a corresponding disk speed represents the electrical energy 1602 exchanged by magnetic interaction during one rotation of the disk. A plot of the energy calculated by measuring torque on the disk for a corresponding disk speed represents the mechanical energy 1604 exchanged by magnetic interactions during one rotation of the disk. The sum of the electrical energy 1602 and mechanical energy 1604 represents the total energy 1606 exchanged by magnetic interactions during a revolution of the disk.

Although illustrative embodiment of the invention are described as having the MUT mounted to a force gauge and an electromagnet fixed in proximity thereto, persons having ordinary skill in the art should appreciate that alternative embodiments of the invention can be implemented by mounting the electromagnet to the force gauge and fixing the MUT in proximity thereto within the scope of the invention. Further, while an electromagnet is described, it should be appreciate that other magnetic elements can be alternatively implemented. And, while a force gauge and an oscilloscope are used as part of the instrumentation of the illustrative embodiments, other measurement techniques and instrumentation can be alternatively implemented.

Although a material under test is described herein as a partially demagnetized neodymium magnet, it should be appreciated that any of various other magnetic materials could be alternatively implemented.

While the invention has been described with reference to an exemplary embodiment, it should be understood by those skilled in the art that various changes, omissions and/or additions may be made and equivalents may be substituted for elements thereof without departing from the spirit and scope of the invention. In addition, many modifications may be made to adapt a particular situation or material to the teachings of the invention without departing from the scope thereof. Therefore, it is intended that the invention not be limited to the particular embodiment disclosed as the best mode contemplated for carrying out this invention, but that the invention will include all embodiments falling within the scope of the appended claims. Moreover, unless specifically stated any use of the terms first, second, etc. do not denote any order or importance, but rather the terms first, second, etc. are used to distinguish one element from another.

What is claimed is:

1. A method for measuring magnetic force response time, comprising:
mounting a first magnet proximate to a material under test;
mounting a measuring device to the material under test for measuring forces between the first magnet and the material under test;
energizing the first magnet;
recording the force versus time measured by the measuring device in response to energizing the first magnet; and
recording the current versus time through the first magnet in response to energizing the first magnet.

2. The method of claim 1, wherein the material under test comprises a partially de-magnetized permanent magnet.

3. The method of claim 2, wherein the partially demagnetized permanent magnet comprises a neodymium magnet.

4. The method of claim 1, wherein the first magnet is a fast acting air coil electromagnet.

5. The method of claim 4, wherein the electromagnet comprises eight turns of 1.5 mm diameter insulated copper wire forming a coil having an outside diameter of about 7 mm.

6. The method of claim 1, wherein the first magnet comprises an electromagnet being mounted proximate to the material under test.

7. The method of claim 1, wherein the first measuring device comprises a force gauge.

8. The method claim 1, wherein the first magnet is in a fixed position relative to the second magnet.

9. The method of claim 1, wherein the first magnet comprises an electromagnet and wherein energizing the electromagnet comprises:
connecting a DC voltage source having a voltage value, a resistor having a resistance value, and a first switch in series across terminal of the electromagnet; and
cycling the first switch from an open position to a closed position.

10. The method of claim 9, wherein the current versus time is measured by:
connecting an oscilloscope across the resistor;
measuring the voltage across the resistor; and
dividing the voltage by the resistance value.

11. The method of claim 10, wherein the force versus time is measured by:
connecting the force gauge to the oscilloscope; and
measuring a force signal output by the force gauge to the oscilloscope.

12. The method of claim 9, comprising;
reversing the polarity of the DC voltage source;
cycling the first switch from an open position to a closed position; and
repeating the recording of force versus time and current versus time to demonstrate equality of attractive and repulsive magnetic interactions.

13. The method of claim 9, comprising:
repeatedly energizing the electromagnet by:
closing the first switch;
connecting relay in series with the DC voltage source;
connecting a pulse generator to the relay; and
applying a pulse train from the pulse generator to the relay, wherein the pulse train repeatedly energizes the relay.

14. The method of claim 13, further comprising:
measuring the current versus time and the force versus time prior to repeatedly energizing the electromagnet; and
measuring the current versus time and the force versus time after repeatedly energizing the electromagnet.

15. A method of measuring energy exchanged due to the relative motion of magnetic materials, comprising:
mounting a permanent magnet on a disk having an axis of rotation;
revolving the disk at a constant speed around the axis of rotation;
mounting a passive electromagnet proximate to the circular path;
measuring current induced in the electromagnet for corresponding angular displacements of the permanent magnet around the circular path;
measuring torque on the disk for corresponding angular displacements for the permanent magnet around the circular path;
calculating mechanical energy exchanged as a function of the measured torque and the speed of the disk;
calculating electrical energy exchanged as a function of the measured current and the speed of the disk; and
adding the absolute value of calculated electrical energy absolute value of the calculated mechanical energy together to produce a measurement of the total energy exchanged.

16. The method of claim 13, comprising:
for different constant speeds, repeating the steps of revolving, measuring current, measuring torque, calculating mechanical energy, calculating electrical energy and adding absolute values.

17. The method of claim 16, further comprising:
plotting the total energy exchanged versus rotational speed for each of the different constant speeds to demonstrate that the energy exchanged is related to the time duration of the interaction.

18. The method of claim 15, comprising utilizing magnetic viscosity of the electromagnet to reduce torque acting on the disk by increasing the rotational speed of the disk.

19. The method of claim 15, comprising utilizing magnetic viscosity of the electromagnet to delay a point of maximum magnetic flux by increasing rotational speed of the disk.

20. The method of claim 15, wherein the permanent magnet comprises a neodymium magnet.

21. The method of claim 15, wherein the measuring current induced in the electromagnet versus time is performed by:
connecting a resistor across terminals of the electromagnet;
utilizing an oscilloscope to measure voltage across the resistor versus time;
dividing the voltage by the a resistance value of the resistor; and
determining angular position of the disk as a function of time.

22. A system for utilizing magnetic viscosity to reduce the energy of an interaction, the system comprising:
a permanent magnet mounted to a disk, the disk having an axis of rotation to establish a circular path of the permanent magnet;
a passive electromagnet mounted proximate to the path, the permanent magnet having a ferromagnetic core;
a motor adapted to rotate the disk at a plurality of constant speeds;
a current measuring apparatus connected to measure current through the electromagnet as a function of angular position of the disk; and
a torque measuring apparatus adapted to measure torque on the disk as a function of angular position of the disk.

23. The system of claim 22, further comprising:
means for calculating mechanical energy exchanged as a function of the measured torque and the speed of the disk;
means for calculating electrical energy exchanged as a function of the measured current and the speed of the disk; and
means for adding the absolute value of calculated electrical energy and the absolute value of the calculated mechanical energy together to produce a measurement of the total energy exchanged.

24. A system for utilizing magnetic viscosity to reduce the energy of an interaction, the system comprising:
a first magnet mounted to a movable element, the movable element having a path for movement proximate to the first magnet;
a second mounted proximate to the path for movement;
an actuator imparting movement to the moveable element as a selected one of a plurality of constant speeds;
a first measuring apparatus connected to measure at least one electrical characteristic of the first magnet as a function of a position of the movable element; and
a second measuring apparatus adapted to measure force on the movable element as a function of position of the movable element.

25. The system of claim 24, wherein movable element comprises a disk having an axis of rotation to establish a circular path of the first magnet.

26. The system of claim 25, wherein the second measuring apparatus comprises a torque measuring apparatus adapted to measure torque on the disk as a function of angular position of the disk.

27. The system of claim 25, wherein the actuator comprises a motor adapted to rotate the disk.

28. The system of claim 24, wherein the first magnet comprises a permanent magnet and the second magnet is an electromagnet.

29. The system of claim 28, wherein the first measuring apparatus comprises a current measuring apparatus connected to measure current through the electromagnet.
